(19) United States
(12) Patent Application Publication
(10) Pub. No.: US 2023/0120789 A1
(43) Pub. Date: Apr. 20, 2023

(54) EXPOSURE APPARATUS

(71) Applicant: PlayNitride Display Co., Ltd., MiaoLi County (TW)

(72) Inventors: Po-Wei Chiu, MiaoLi County (TW); Sheng-Yuan Sun, MiaoLi County (TW); Yen-Yeh Chen, MiaoLi County (TW)

(73) Assignee: PlayNitride Display Co., Ltd., MiaoLi County (TW)

(21) Appl. No.: 17/583,157

(22) Filed: Jan. 24, 2022

(30) Foreign Application Priority Data
Oct. 20, 2021 (TW) 110138808

(51) Int. Cl. G03F 7/213; G03F 7/20

(52) U.S. Cl. CPC G03F 7/213; G03F 7/2008; G03F 2007/2067

(57) ABSTRACT

An exposure apparatus including a micro light emitting diode display unit and a first projection optical system is provided. The micro light emitting diode display unit has a plurality of micro light emitting diodes. The micro light emitting diode display unit is adapted to individually control light emission signals of the micro light emitting diodes and forming a predetermined pattern. The first projection optical system is disposed on a light emitting path of the micro light emitting diode display unit. The first projection optical system is configured to form an exposure pattern on a photosensitive material layer at once by applying the predetermined pattern.

### CROSS-REFERENCE TO RELATED APPLICATION

This application claims the priority benefit of Taiwan patent application serial no. 110138808, filed on Oct. 20, 2021. The entirety of the above-mentioned patent application is hereby incorporated by reference herein and made a part of this specification.

### BACKGROUND

### Technical Field

The disclosure relates to a semiconductor manufacturing apparatus and particularly relates to an exposure apparatus.

### Description of Related Art

An exposure apparatus may be applied to fabricate semiconductor devices, for instance. The exposure apparatus projects patterns of a photomask onto a substrate with a photoresist coating (e.g., a glass plate, a semiconductor wafer, and so on) via a projection optical system. Here, a stepper is one of the most common exposure apparatuses. The stepper exposes a single or multiple patterns of the photomask to each irradiated target zone on the substrate by repetitive and step-by-step movement.

As the size of the substrate increases, to reduce the number of times of exposures on one single substrate, the size of the photomask used in the exposure apparatus inevitably increases. This leads to an increase in costs of the photomask. In addition, in order to increase optical path collimation of an exposure light source, most exposure apparatuses are equipped with complex and expensive optical lens modules, such as a digital micromirror device with a complex design to control light spot switch. As a result, manufacturing costs of the exposure apparatus cannot be effectively reduced. Therefore, an exposure apparatus that is adapted to various sizes of different substrates and characterized by a cost advantage is to be developed.

### SUMMARY

The disclosure provides an exposure apparatus with a cost advantage and process flexibility, and patterning processes can be conducted even without a photomask.

In an embodiment of the disclosure, an exposure apparatus including a micro light emitting diode (LED) display unit and a first projection optical system is provided. The micro LED display unit has a plurality of micro light emitting diodes (LEDs) and is adapted to individually control light emission signals of the micro LEDs and form a predetermined pattern. The first projection optical system is disposed on a light exit path of the micro LED display unit and configured to form an exposure pattern on a photosensitive material layer by applying the predetermined pattern at once.

According to an embodiment of the disclosure, the exposure pattern is the same as the predetermined pattern or is reduced by a factor when compared to the predetermined pattern.

According to an embodiment of the disclosure, the exposure apparatus further includes a plurality of micro lenses disposed on the light exit path of the micro LED display unit and located between the micro LED display unit and the first projection optical system.

According to an embodiment of the disclosure, the micro lenses are disposed on a light exit surface of the micro LED display unit, and the micro lenses are arranged respectively corresponding to the micro LEDs.

According to an embodiment of the disclosure, the exposure apparatus further includes a second projection optical system disposed on the light exit path of the micro LED display unit and located between the micro LED display unit and the micro lenses.

According to an embodiment of the disclosure, a light blocking pattern layer is disposed among side walls of the micro lenses of the micro LED display unit of the exposure apparatus.

According to an embodiment of the disclosure, the exposure apparatus further includes a light shielding pattern layer disposed among side walls of the micro LEDs.

According to an embodiment of the disclosure, the exposure apparatus further includes a light shielding pattern layer disposed between the micro LED display unit and the first projection optical system; the light shielding pattern layer has a plurality of openings respectively corresponding to the micro LEDs.

According to an embodiment of the disclosure, the first projection optical system of the exposure apparatus has a projection demagnification ratio, and a ratio of a dimension of the exposure pattern to a dimension of the predetermined pattern is equal to the projection demagnification ratio.

According to an embodiment of the disclosure, the exposure apparatus further includes a moving platform and a control unit. The moving platform is disposed on one side of the first projection optical system away from the micro LED display unit, the photosensitive material layer is disposed on the moving platform, and the moving platform is adapted to drive the photosensitive material layer to move along at least one direction. The control unit is electrically coupled to the moving platform and the micro LED display unit and configured to control movement of the moving platform and the light emission signals of the micro LEDs of the micro LED display unit.

According to an embodiment of the disclosure, the exposure apparatus further includes a first moving platform, an accommodation space, a second moving platform, and a control unit. The micro LED display unit is disposed on the first moving platform, and the first moving platform is adapted to drive the micro LED display unit to move along at least one direction. The accommodation space is arranged on one side of the first projection optical system away from the micro LED display unit, and the photosensitive material layer is disposed in the accommodation space. The second moving platform is disposed on one side of the accommodation space away from the first projection optical system and adapted to drive the exposure pattern to move along a lifting direction. Here, the lifting direction is perpendicular to the at least one direction. The control unit is electrically coupled to the first moving platform, the second moving platform, and the micro LED display unit and configured to control movements of the first moving platform and the second moving platform and the light emission signals of the micro LEDs of the micro LED display unit.

In view of the above, in the exposure apparatus provided in one or more embodiments of the disclosure, the arrangement of the micro LEDs acting as the exposure sources are conducive to simplifying the structural design of the exposure apparatus. Besides, the light emission intensities of the micro LEDs are individually controlled to generate light shielding (light transmitting) patterns of conventional photomasks, which not only reduces manufacturing costs of the photomasks but also saves time of switching between different photomasks in the exposure process. Thereby, production performance may be improved.

To make the above more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic view of an exposure apparatus according to a first embodiment of the disclosure.

FIG. 2A and FIG. 2B are schematic enlarged views illustrating partial zones of the photosensitive substrate depicted in FIG. 1 after an exposure and development process is performed on the photosensitive substrate.

FIG. 3 is a schematic view of an exposure apparatus according to a second embodiment of the disclosure.

FIG. 4A and FIG. 4B are schematic cross-sectional views of micro LED display units according to some other modified embodiments.

FIG. 5 is a schematic view of an exposure apparatus according to a third embodiment of the disclosure.

FIG. 6 is a schematic view of an exposure apparatus according to a fourth embodiment of the disclosure.

### DESCRIPTION OF THE EMBODIMENTS

In the accompanying drawings, thicknesses of layers, films, panels, zones and regions, and the like are exaggerated for clarity. It should be understood that when an element, such as a layer, a film, a zone, a region, or a substrate, is referred to as being “on” or “connected to” another element, it can be directly on or connected to such another element, or intervening elements may also be present. By contrast, when an element is referred to as being “directly on” or “directly connected to” another element, there is no intervening element present. As used herein, the term “connected” may refer to “physically connected” and/or “electrically connected”. Therefore, “electrical connection” or “coupling” between two elements may be understood as intervening elements existing between the two elements.

Hereinafter, exemplary embodiments of the invention are described in detail, and examples of the exemplary embodiments are conveyed via the drawings. Wherever possible, the same reference numerals are used in the figures and the descriptions to refer to the same or similar elements.

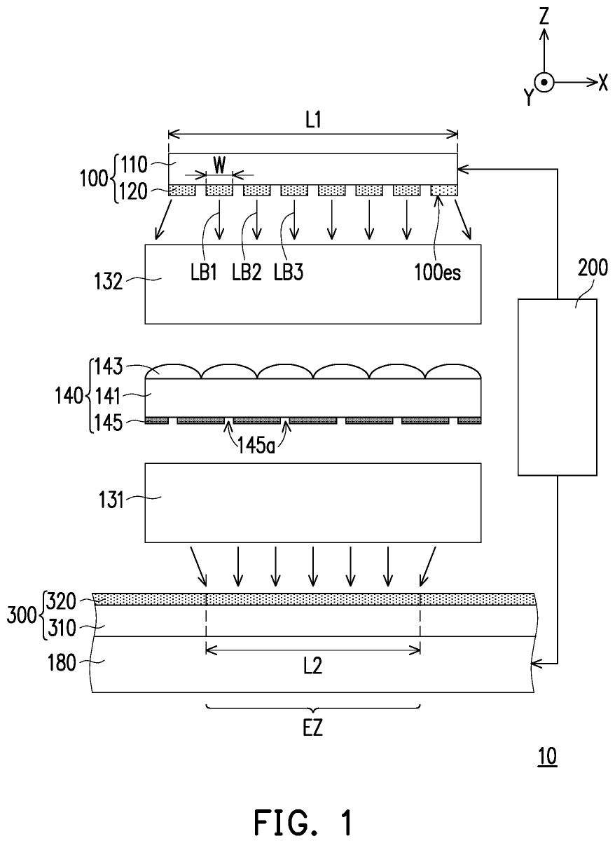

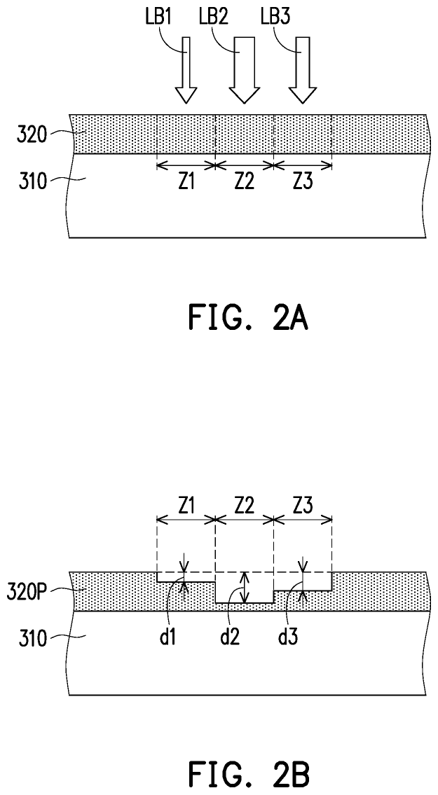

FIG. 1 is a schematic view of an exposure apparatus according to a first embodiment of the disclosure. FIG. 2A and FIG. 2B are schematic enlarged views illustrating partial zones of the photosensitive substrate depicted in FIG. 1 after an exposure and development process is performed on the photosensitive substrate.

With reference to FIG. 1, an exposure apparatus 10 includes a micro LED display unit 100, a first projection optical system 131, and a moving platform 180. The micro LED display unit 100 includes a circuit substrate 110 and a plurality of micro LEDs 120 disposed on the circuit substrate 110. For instance, the micro LEDs 120 may be electrically connected to the circuit substrate 110 after a transfer process is performed, and may define a light exit surface 100es of the micro LED display unit 100. The circuit substrate 110 is, for instance, a TFT substrate, a printed circuit board, a CMOS substrate, or any other substrate with circuits. More specifically, the micro LED display unit 100 is adapted to individually control the micro LEDs 120 to send light emission signals on the light exit surface 100es and form a predetermined pattern; for instance, a driving current or light emitting time of each of the micro LEDs 120 may be controlled to adjust the intensity of light for displaying the predetermined pattern. In this embodiment, a light emission wavelength of the micro LEDs 120 may range from 365 nm to 436 nm, which should however not be construed as a limitation in the disclosure. In other embodiments, the light emission wavelength of the micro LEDs 120 may also be a wavelength of deep ultraviolet light less than 365 nm.

In particular, the micro LEDs 120 may come from wafers with different wavelengths and are disposed on the circuit substrate 110 through the transfer process; here, the micro LEDs 120 of different wavelengths may have a wavelength difference of greater than 5 nm, which retains the advantages of a multi-waveband mercury lamp and allows better reaction of the photosensitive material. The micro LEDs 120 may also come from the same wafer but have a wavelength difference of less than 5 nm and are disposed on the circuit substrate 110 through the transfer process, which may increase the utilization rate of the wafer without affecting the exposure yield. The selection of the photosensitive material is determined according to actual needs and should not be construed as a limitation in the disclosure.

The first projection optical system 131 and the moving platform 180 are disposed on a light exit path of the micro LED display unit 100, and the moving platform 180 is disposed on one side of the first projection optical system 131 away from the micro LED display unit 100. In this embodiment, the moving platform 180 is suitable for holding a photosensitive substrate 300 and suitable for driving the photosensitive substrate 300 to move along at least one direction (e.g., a direction X and a direction Y). The first projection optical system 131 is configured to project the predetermined pattern onto the photosensitive substrate 300 for exposure. Particularly, the photosensitive substrate 300 may include a substrate 310 and a photosensitive material layer 320 coated on the substrate 310. Light (e.g., light LB1, light LB2, and light LB3) for forming the predetermined pattern is adjusted by an optical path of the first projection optical system 131 and then projected on the photosensitive material layer 320 for exposure and for forming an exposure pattern. The first projection optical system 131 is, for instance, one single lens or a system containing a plurality of micro lens arrays for converge or diverge light.

To be specific, the predetermined pattern is formed by arranging a plurality of micro LEDs 120 on the micro LED display unit 100. Here, a non-light-emitting zone on the micro LED display unit 100 may be equivalent to a light shielding zone on a conventional photomask, and the light-emitting zone may be equivalent to a transparent zone on the conventional photomask. In other words, the micro LED display unit 100 provided in an embodiment of the disclosure not only acts as an exposure source of the exposure apparatus 10 but also allows, due to the adjustability of the brightness of emitted light of the micro LEDs 120, the micro LED display unit 100 with different intensities of light to achieve the distribution of the exposure light intensity as is achieved by a conventional photomask, e.g., a half tone mask.

On the other hand, different from the point light source used in the conventional exposure apparatus, the micro LED display unit 100 provided herein may be regarded as an area light source. Therefore, unlike the conventional point exposure process, the exposure apparatus 10 provided in one or more embodiments of the disclosure directly performs a patterning process on the photosensitive material layer 320 by applying a surface exposure method. As such, it is not necessary to additionally design a complicated digital micromirror device for controlling a light spot switch, which may simplify the optical path design of the exposure apparatus 10. Besides, the manufacturing cost of the conventional photomasks and the time of switching between different photomasks in the manufacturing process may both be reduced. Moreover, the grayscale exposure and the production of large-area 2D patterns and 3D projects may be increased, which is conducive to the improvement of production efficiency.

With reference to FIG. 2A and FIG. 2B, for instance, the light LB1, the light LB2, and the light LB3 coming from three adjacent micro LEDs 120 have different light energies (i.e., the intensities of the emitted light of the three micro LEDs 120 are different). The light LB2, the light LB3, and the light LB1 are arranged in a descending order according to the light energy. Therefore, three zones of the photosensitive material layer 320 irradiated by the lights at the same time, e.g., a zone Z1, a zone Z2, and a zone Z3, receive different exposure doses. More specifically, the zone Z2, the zone Z3, and the zone Z1 are arranged in a descending order according to their respective exposure doses (i.e., from the largest to the smallest).

In this embodiment, a material of the photosensitive material layer 320 is, for instance, a positive photoresist material. Therefore, after the development process, groove patterns (i.e., an exposure pattern 320P) with different depths are formed in the three zones of the photosensitive material layer 320. For instance, the exposure pattern 320P has a depth d1, a depth d2, and a depth d3 in the three grooves of the zone Z1, the zone Z2, and the zone Z3, respectively. Here, the depth d2 of the zone Z2 that receives the most exposure dose has the largest value, the depth d3 of the zone Z3 that receives the second most exposure dose has the second largest value, and the depth d1 of the zone Z1 that receives the least exposure has the smallest value. More specifically, there is a mapping relationship between the distribution of the emitted light intensity (i.e., the predetermined pattern) of the micro LED display unit 100 and the exposure pattern 320P. Compared with the conventional art that requires multiple exposures to reach zones of different depths, the embodiment may achieve exposures on the zones of different depths at the same time due to the differences in the light energies.

In order to improve resolution (or accuracy) of the exposure pattern, the exposure apparatus 10 may selectively include a second projection optical system 132 and a light modulation device 140. The second projection optical system 132 is disposed between the micro LED display unit 100 and the first projection optical system 131. The light modulation device 140 is disposed on the light exit path of the micro LED display unit 100 and located between the first projection optical system 131 and the second projection optical system 132. For instance, the second projection optical system 132 may be one single lens or a system containing a plurality of micro lens arrays to converge or diverge light, which should however not be construed as a limitation in the disclosure. According to other requirements for the manufacturing process, the exposure apparatus may also be additionally equipped with only one of the second projection optical system 132 and the light modulation device 140.

In this embodiment, the light modulation device 140 includes a light transmitting substrate 141, a plurality of micro lenses 143, and an array layer 145; here, the micro lenses 143 are disposed on one surface of the light transmitting substrate 141 facing the second projection optical system 132, and the array layer 145 is disposed on the other surface of the light transmitting substrate 141 facing the first projection optical system 131. For instance, the micro lenses 143 may be arranged in an array on the light transmitting substrate 141 along the direction X and the direction Y, respectively, and holes 145a of the array layer 145 respectively are arranged corresponding to the geometric center of the micro lenses 143. The second projection optical system 132 is adapted to converge the light from the micro LED display unit 100 onto the light modulation device 140, and the first projection optical system 131 is adapted to converge the light passing through the holes 145a of the light modulation device 140 onto the photosensitive material layer 320. In some embodiments, the light modulation device 140 may be a spatial filter which may filter out noise of the emitted light of the micro LEDs 120 to achieve a favorable exposure effect.

More specifically, in this embodiment, the first projection optical system 131 may have a projection demagnification ratio. A ratio of a dimension of the exposure pattern to a dimension of the predetermined pattern of the micro LED display unit 100 (and the distribution of the emitted light intensity of the micro LEDs 120) respectively on the X-Y plane may be equal to the projection demagnification ratio. For instance, a length L2 of the exposure pattern (or an exposure zone EZ) along the direction X is less than a length L1 of the predetermined pattern along the direction X, which should however not be construed as a limitation in the disclosure. In other embodiments, the dimension of the exposure pattern and the dimension of the predetermined pattern respectively on the X-Y plane may also be approximately the same. That is, the first projection optical system 131 may not have the projection demagnification ratio, and the micro LED display unit 100 does not act as an exposure light source reduced by a factor. In other words, according to the design of the exposure apparatus, the exposure pattern may be the same as the predetermined pattern, and the resultant exposure apparatus may have a relatively small size and favorable exposure accuracy. The exposure apparatus may also be designed to have the exposure pattern which can be reduced by a factor to when compared to the predetermined pattern, so as to occupy a relatively large area and achieve accurate exposure.

Since each of the micro LEDs 120 of the micro LED display unit 100 is an independent exposure source whose distribution of the emitted light intensity is controllable, the resolution of the exposure pattern may be improved. In an embodiment, a width w of the light exit surface of the micro LEDs 120 along an arrangement direction (e.g., the direction X or the direction Y) is less than 60 If the width w is greater than or equal to 60 the resolution of the exposure pattern may not be satisfactory. In particular, the width w of the micro LEDs 120 may be less than 10 whereby the micro LEDs 120 may be arranged more densely and have an improved emitted light intensity, so that the micro LEDs 120 may act as the exposure sources in replacement of the general LEDs, and that the resolution of the exposure pattern may be enhanced. On the other hand, an illuminance of the emitted light of the micro LED display unit 100 on the light exit surface 100es is greater than 0.05 μW/cm². If the illuminance is less than 0.05 μW/cm², the resultant exposure energy is insufficient.

In this embodiment, the exposure apparatus 10 further includes a control unit 200 electrically coupled to the micro LED display unit 100 and the moving platform 180. The control unit 200 is configured to receive a setting command from a human-machine interface and, based on preset process parameters or parameter values fed back in a real-time manner in the process, drive the moving platform 180 and the micro LED display unit 100 to operate according to a preset process. For instance, in the exposure process, the control unit 200 may drive the moving platform 180 to move to a position coordinate, so that a to-be-exposed zone of the photosensitive substrate 300 is located on the optical path of the exposure light source (i.e., the micro LED display unit 100) and the projection optical system. After the movement is completed, the control unit 200 controls each of the micro LEDs 120 individually according to the preset process parameters (e.g., the illuminance, the exposure time); for instance, the control unit 200 controls the current of each of the micro LEDs 120, so that the micro LED display unit 100 emits light to perform the exposure process on the photosensitive material layer 320.

Other embodiments will be provided below to describe the disclosure in detail, wherein the same components are marked by the same reference numbers, and the description of the same technical content will be omitted. The reference to the explanation of the omitted parts may be found in the previous embodiments, and the omitted parts will not be further described hereinafter.

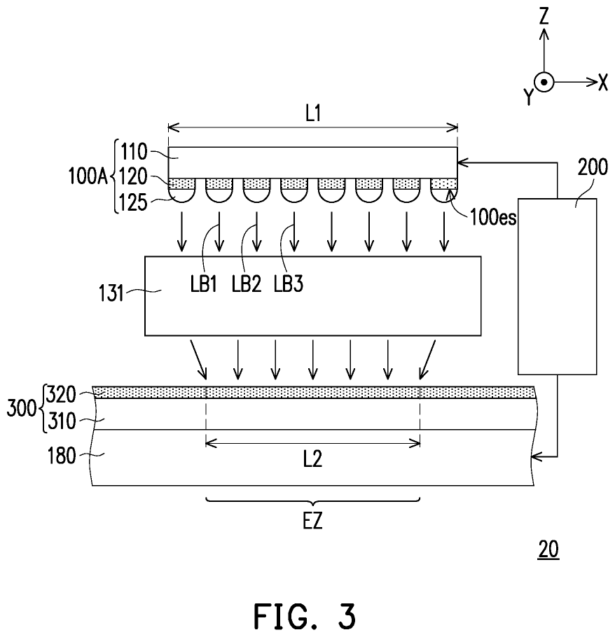

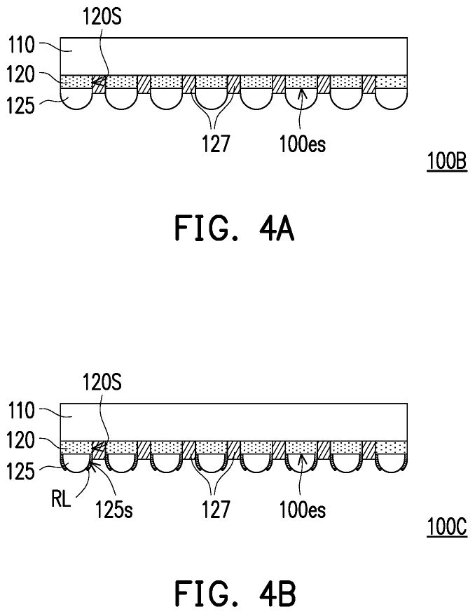

FIG. 3 is a schematic view of an exposure apparatus according to a second embodiment of the disclosure. FIG. 4A and FIG. 4B are schematic cross-sectional views of micro LED display units according to some other modified embodiments. With reference to FIG. 3, the difference between an exposure apparatus 20 provided in this embodiment and the exposure apparatus 10 depicted in FIG. 1 lies in the different structures of the exposure apparatuses. Specifically, in this embodiment, a plurality of micro lenses 125 are directly provided on the light exit surface 100es of a micro LED display unit 100A, and the micro lenses 125 are respectively disposed corresponding to the micro LEDs 120.

The arrangement of the micro lenses 125 may change the light emitting pattern of the micro LEDs 120, e.g., to form a uniform light emitting pattern. Therefore, the configuration of the light modulation device 140 in FIG. 1 may be omitted, and the resultant exposure apparatus 20 may be more cost-effective. The effect achieved by the first projection optical system 131 on the light emitted by the micro LED display unit 100A is similar to the effect achieved by the first projection optical system 131 on the light coming from the light modulation device 140 in FIG. 1; hence, please refer to the descriptions provided in the previous embodiment, and no further explanation will be provided hereinafter.

However, this may not be construed as a limitation in the disclosure. With reference to FIG. 4A, in another embodiment, a micro LED display unit 100B may selectively include a light shielding pattern layer 127 disposed among side walls 120S of the micro LEDs 120, and the light shielding pattern layer 127 may further protrude from the light exit surface 100es toward the first projection optical system 131 and may then be disposed between at least part of the micro lenses 125. Thereby, lateral light leakage of the micro LEDs 120 may be blocked, so as to prevent the reduction of the patterning resolution caused by the lateral light leakage during exposure. The light shielding pattern layer 127 may be a light absorbing layer or a reflective layer. If the light shielding pattern layer 127 is a light absorbing layer, a material of the light shielding pattern layer 127 may include black photoresist, black resin, and so forth. If the light shielding pattern layer 127 is a reflective layer, a material of the light shielding pattern layer 127 may include metal (e.g., aluminum) or metal oxide (e.g., aluminum oxide), which should however not be construed as a limitation in the disclosure.

With reference to FIG. 4B, in another embodiment, the side wall 125s of each micro lens 125 of the micro LED display unit 100C may be selectively covered by a light blocking pattern layer RL. The light blocking pattern layer RL may limit light exit angles of the micro LEDs 120 to be within a predetermined range. That is, the light emitting pattern of the micro LED display unit 100C may achieve favorable collimated and collective effects to prevent lateral stray light. Thereby, the exposure resolution of the exposure apparatus may be improved. The light blocking pattern layer RL may be a light absorbing layer or a reflective layer and may be made of a material different from the material of the light shielding pattern layer 127. For instance, the light shielding pattern layer 127 is a light absorbing layer, and the light blocking pattern layer RL is a reflective layer, so as to achieve a better light emitting efficiency, which should however not be construed as a limitation in the disclosure.

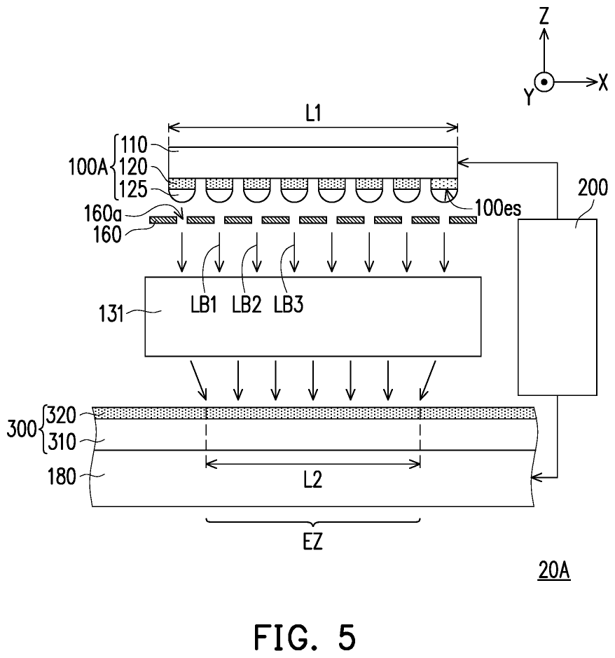

FIG. 5 is a schematic view of an exposure apparatus according to a third embodiment of the disclosure. With reference to FIG. 5, the difference between an exposure apparatus 20A provided in this embodiment and the exposure apparatus 20 depicted in FIG. 3 lies in the different arrangement of the light shielding pattern layer. Specifically, a light shielding pattern layer 160 of the exposure apparatus 20A is disposed between the micro LED display unit 100A and the first projection optical system 131 and has a plurality of openings 160a disposed corresponding to the micro LEDs 120, respectively. A certain distance exists between the light shielding pattern layer 160 and the micro LED display unit 100A according to this embodiment; therefore, in comparison with the exposure apparatus depicted in FIG. 4A, the light emitted by the micro LED display unit 100A of the exposure apparatus 20A in FIG. 5 may achieve better light collimation effects after the light passes through the light shielding pattern layer 160 provided in this embodiment, thereby improving the exposure resolution of the exposure apparatus 20A. In an embodiment not shown in the drawings, the light shielding pattern layer may not only be disposed between the micro LED display unit 100A and the first projection optical system 131 but also be simultaneously located among side walls 120S of the micro LEDs 120 (as shown in FIG. 4B). Accordingly, the exposure apparatus may achieve favorable exposure effect.

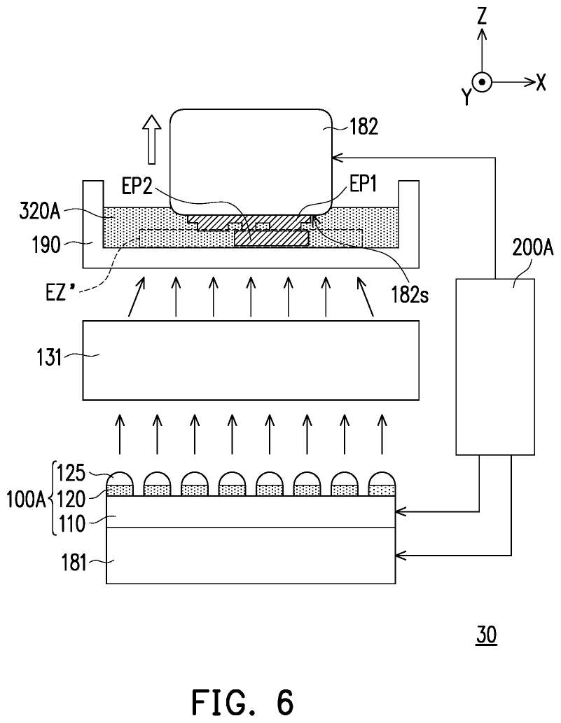

FIG. 6 is a schematic view of an exposure apparatus according to a fourth embodiment of the disclosure. As shown in FIG. 6, an exposure apparatus 30 includes the micro LED display unit 100A, the first projection optical system 131, a first moving platform 181, a second moving platform 182, an accommodation space 190, and a control unit 200A. In this embodiment, the micro LED display unit 100A is disposed on the first moving platform 181, and the first moving platform 181 is adapted to drive the micro LED display unit 100A to move in at least one direction (e.g., the direction X and the direction Y).

The first projection optical system 131 is disposed on the light exit path of the micro LED display unit 100A and located between the first moving platform 181 and the accommodation space 190. The effect achieved by the first projection optical system 131 on the light emitted by the micro LED display unit 100A is similar to the effect achieved by the exposure apparatus 20 depicted in FIG. 3; hence, please refer to the descriptions provided in the previous embodiment, and no further explanation will be provided hereinafter.

The accommodation space 190 is arranged on one side of the first projection optical system 131 away from the micro LED display unit 100A and located between the micro LED display unit 100A and the second moving platform 182. A photosensitive material layer 320A is disposed in the accommodation space 190. Since the light emitted by the micro LED display unit 100A enters the photosensitive material layer 320A from the bottom of the accommodation space 190, the bottom of the accommodation space 190 must have a certain degree of light transmittance within the wavelength range of the light. A material of the entire accommodation space 190 or a part of the accommodation space 190 located on the exposure optical path may, for instance, be glass or quartz, which should however not be construed as a limitation in the disclosure. In this embodiment, the photosensitive material layer 320A is, for instance, made of a liquid resin material or any other suitable light curing material.

The second moving platform 182 is disposed on one side of the accommodation space 190 away from the first projection optical system 131 and adapted to move in a direction away from the accommodation space 190 (e.g., a direction Z). Note that the second moving platform 182 continuously moves during the exposure process performed on the photosensitive material layer 320A. More specifically, the second moving platform 182 moves along a lifting direction (i.e., the direction Z), and the lifting direction may be perpendicular to the direction X and the direction Y (or the X-Y plane).

In this embodiment, an exposure zone EZ″ near the bottom of the accommodation space 190 of the photosensitive material layer 320A is irradiated by exposure light coming from the micro LED display unit 100A and modulated by the first projection optical system 131, and a photosensitive material in the exposure zone EZ″ starts to be cured after the photosensitive material is exposed. At the same time, the second moving platform 182 continues to move away from the exposure zone EZ″ to drive the newly cured exposure pattern to move away from the exposure zone EZ″ and perform an exposure process on another predetermined pattern.

During the entire exposure process, as the second moving platform 182 is lifted, the predetermined pattern of the micro LED display unit 100A configured for exposure may also change. For instance, when the exposure process starts, the photosensitive material layer 320A performs a curing process to form a corresponding first exposure pattern EP1 on a surface 182s of the second moving platform 182 according to the first predetermined pattern. After the first exposure pattern EP1 leaves the exposure zone EZ″, the micro LED display unit 100A switches to the second predetermined pattern and again performs an exposure process on the photosensitive material filling the exposure zone EZ″ to form a second exposure pattern EP2. Said steps are repeated to form a 3D object stacked by a plurality of exposure patterns. More specifically, the exposure apparatus 30 provided in this embodiment is suitable for 3D printing of 3D objects.

In the conventional 3D printing technology, the point-by-point curing method is adopted; by contrast, the exposure apparatus 30 provided in this embodiment applies the micro LED display unit 100A as an area light source to perform a surface exposure process on the photosensitive material layer 320. Thereby, the optical path design of the exposure apparatus 30 may be simplified, and the time spent on the 3D printing process may be effectively reduced, which is conducive to an effective improvement of production performance.

In order to increase the printing range on the X-Y plane, the first moving platform 181 may also drive the micro LED display unit 100A to move along the direction X or the direction Y. Therefore, in the exposure process for forming the first exposure pattern, the second moving platform 182 may perform another lifting process after the micro LED display unit 100A completes a scanning and exposure process on the X-Y plane.

In this embodiment, the control unit 200A is electrically coupled to the first moving platform 181, the second moving platform 182, and the micro LED display unit 100A and configured to control the movement of the first moving platform 181 and the movement of the second moving platform 182 and the light emission of the micro LED display unit 100A. The control unit 200A is configured to receive a setting command from a human-machine interface and, based on preset process parameters or parameter values fed back in a real-time manner in the process, drive the first moving platform 181, the second moving platform 182, and the micro LED display unit 100A to operate according to a preset process.

For instance, in the exposure process, the control unit 200A may firstly drive the first moving platform 181 to move to a position coordinate. After the movement is completed, the control unit 200 controls each of the micro LEDs 120 individually according to the preset process parameters (e.g., the illuminance, the exposure time), and the predetermined pattern is applied to drive the micro LED display unit 100A to emit light to perform the exposure process on the photosensitive material in the exposure zone EZ″. The second moving platform 182 is then lifted to an altitude coordinate, and the micro LED display unit 100A is driven to emit light according to another predetermined pattern to perform another exposure process on the photosensitive material layer re-filling the exposure zone EZ″.

To sum up, in the exposure apparatus provided in one or more embodiments of the disclosure, the arrangement of the micro LEDs acting as the exposure sources may be conducive to simplifying the structural design of the exposure apparatus. Besides, the light emission intensities of the micro LEDs are individually controlled to generate the light shielding (light transmitting) patterns of the conventional photomasks, which not only reduces the manufacturing costs of the photomasks but also saves the time of switching between different photomasks in the exposure process. Thereby, the production performance may be improved.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. An exposure apparatus, comprising:
a micro light emitting diode display unit, having a plurality of micro light emitting diodes and adapted to individually control light emission signals of the micro light emitting diodes and form a predetermined pattern; and
a first projection optical system, disposed on a light exit path of the micro light emitting diode display unit and configured to form an exposure pattern on a photosensitive material layer by applying the predetermined pattern at once.

2. The exposure apparatus according to claim 1, wherein the exposure pattern is the same as the predetermined pattern or is reduced by a factor when compared to the predetermined pattern.

3. The exposure apparatus according to claim 1, further comprising:
a plurality of micro lenses, disposed on the light exit path of the micro light emitting diode display unit and located between the micro light emitting diode display unit and the first projection optical system.

4. The exposure apparatus according to claim 3, wherein the micro lenses are disposed on a light exit surface of the micro light emitting diode display unit, and the micro lenses are arranged respectively corresponding to the micro light emitting diodes.

5. The exposure apparatus according to claim 3, further comprising:
a second projection optical system, disposed on the light exit path of the micro light emitting diode display unit and located between the micro light emitting diode display unit and the micro lenses.

6. The exposure apparatus according to claim 3, wherein a light blocking pattern layer is disposed among side walls of the micro lenses.

7. The exposure apparatus according to claim 1, further comprising:
a light shielding pattern layer, disposed among side walls of the micro light emitting diodes.

8. The exposure apparatus according to claim 1, further comprising:
a light shielding pattern layer, disposed between the micro light emitting diode display unit and the first projection optical system and having a plurality of openings respectively corresponding to the micro light emitting diodes.

9. The exposure apparatus according to claim 1, wherein the first projection optical system has a projection demagnification ratio, and a ratio of a dimension of the exposure pattern to a dimension of the predetermined pattern is equal to the projection demagnification ratio.

10. The exposure apparatus according to claim 1, further comprising:
a moving platform, disposed on one side of the first projection optical system away from the micro light emitting diode display unit, wherein the photosensitive material layer is disposed on the moving platform, and the moving platform is adapted to drive the photosensitive material layer to move along at least one direction; and
a control unit, electrically coupled to the moving platform and the micro light emitting diode display unit and configured to control movement of the moving platform and the light emission signals of the micro light emitting diodes of the micro light emitting diode display unit.

11. The exposure apparatus according to claim 1, further comprising:
a first moving platform, wherein the micro light emitting diode display unit is disposed on the first moving platform, and the first moving platform is adapted to drive the micro light emitting diode display unit to move along at least one direction;
an accommodation space, arranged on one side of the first projection optical system away from the micro light emitting diode display unit, the photosensitive material layer being disposed in the accommodation space;
a second moving platform, disposed on one side of the accommodation space away from the first projection optical system and adapted to drive the exposure pattern to move along a lifting direction, wherein the lifting direction is perpendicular to the at least one direction; and
a control unit, electrically coupled to the first moving platform, the second moving platform, and the micro light emitting diode display unit and configured to control movements of the first moving platform and the second moving platform and the light emission signals of the micro light emitting diodes of the micro light emitting diode display unit.
